(19) United States
(12) Patent Application Publication
(10) Pub. No.: US 2024/0243601 A1
(43) Pub. Date: Jul. 18, 2024

(54) SYSTEM AND METHOD OF ANALYSIS OF NOISY APPEARING SIGNALS TO REMOVE THERMAL CONTRIBUTIONS FOR BATTERY CHARGE AND DISCHARGE

(71) Applicant: Iontra Inc, Centennial, CO (US)

(72) Inventors: Daniel A. KONOPKA, Aurora, CO (US); Zhong WANG, Sugar Land, TX (US)

(21) Appl. No.: 18/620,953

(22) Filed: Mar. 28, 2024

Related U.S. Application Data
(63) Continuation-in-part of application No. 18/127,634, filed on Mar. 28, 2023.
(60) Provisional application No. 63/455,252, filed on Mar. 28, 2023.
(60) Provisional application No. 63/324,505, filed on Mar. 28, 2022.

(51) Int. Cl. H02J 7/00; G01R 19/00; G01R 31/389; G01R 31/396

(52) U.S. Cl. CPC H02J 7/00712; G01R 19/0053; G01R 31/389; G01R 31/396

(57) ABSTRACT

Aspects of the present disclosure analyzing one or more signals that include both uncorrelated random signals as well as correlated information pertaining to electrochemical and/or electrodynamic processes occurring within a battery, characterizing the battery for charging, discharging, storage and other uses and/or controlling charging, discharging and other aspects of battery management based on the same.

### CROSS-REFERENCE TO RELATED APPLICATIONS

The present application is a Non-Provisional Utility patent application related to and claiming priority under 35 U.S.C. § 119(e) from U.S. Provisional Patent Application No. 63/455,252 filed Mar. 28, 2023, titled “System and Method of Time-Series Analysis of Noisy Appearing Signals for Battery Charging,” the entire contents of which is incorporated herein by reference for all purposes.

The present application is a Continuation-in-Part patent application related to and claiming priority to U.S. Non-Provisional patent application Ser. No. 18/127,634 filed Mar. 28, 2023, titled “System and Method of Time-Series Analysis of Noisy Appearing Signals for Battery Charging,” which claims benefit of priority under 35 U.S.C. § 119(e) from U.S. Provisional Patent Application No. 63/324,505 filed Mar. 28, 2022, titled “Noise,” both of which are hereby incorporated by reference in their entirety.

### TECHNICAL FIELD

Aspects of the present disclosure analyzing one or more signals that include both uncorrelated random signals as well as correlated information pertaining to electrochemical and/or electrodynamic processes occurring within a battery, characterizing the battery for charging, discharging, storage and other uses and/or controlling charging, discharging and other aspects of battery management based on the same.

### BACKGROUND and INTRODUCTION

Battery powered devices have proliferated and become ubiquitous. Device manufactures are constantly pressing for performance improvement in batteries, particularly as batteries are introduced into devices with relatively higher current demands and power needs. At the same time, consumers demand longer battery life, longer times between charges, and shorter charge times. As such, there is an ongoing and continuous need for improvements in how batteries are managed, charged, and discharged to enhance performance.

It is with these observations in mind, among many others, that the various aspects of the present disclosure were conceived.

### SUMMARY

Aspects of the present disclosure involve a method comprising accessing a noisy signal from a battery where the noisy signal includes uncorrelated noise and correlated signal data and filtering the noisy signal to isolate the correlated signal data. The method further involves processing the correlated signal data to identify at least one of an electrochemical or electrodynamic process within the battery. In various possible implementations, the noisy signal is a voltage measurement or a current measurement at the battery. The signal may also be accessed from memory. The noisy signal may also be a generated measurement, such as an impedance measurement (determination) from at least one of a current measurement and a voltage measurement.

The signal may be obtained during an equilibrium state of the battery, which may be during charge or discharge, or from a probe signal. The equilibrium state of the battery may be considered and occur during a zero-net change to the battery. The signal may also be obtained in a transient state of the battery, which may be associated with a charge signal or a discharge signal. The method may further include filtering the noisy data, such as by way of a domain transform or other filtering technique, to identify the correlated signal data. The domain transform may be one of a partial or fractional domain transform.

The correlated signal data may be associated with plating, and/or dendrite formation and growth. More generally, the correlated signal data may be associated with electrodynamic behavior in the battery. As such, the system and methods discussed herein may act on the identification of electrodynamic behavior of the battery. Conversely, the uncorrelated signal data may be thermal, which can be seen as noise, and hence removing thermal information may help isolate the correlated signal data.

In various possible aspects processing the correlated signal data may involve identifying a bifurcation where a bifurcation is indicative of the onset of an additional electrochemical or electrodynamic process, such as intercalation following by plating being the additional process.

The method may further involve altering a charge parameter (or discharge parameter) based on the identification of the electrochemical or electrodynamic process within the battery.

Another aspect of the present disclosure involves a method comprising, from a signal of an electrochemical device including uncorrelated data and correlated data including pertaining to electrochemical or electrodynamic process of the electrochemical device, filtering the signal to identify the correlated data including information pertaining to the electrochemical or electrodynamic process; and altering a charge parameter based, at least in part, on identification of a bifurcation in the filtered signal. The electrochemical device may be a batter and the signal may be obtained, e.g., measured, during charge or discharge. The charge parameter that is altered may be charge rate, charge voltage and/or duty cycle depending on the type of charge signal. The charge parameter may also comprise a harmonic component of the charge signal.

Further aspects of the present disclosure involve a method of charging a battery comprising generating an electrodynamic parameter from a first version of the electrodynamic parameter computed from a first battery measurement taken in the presence of a current signal at a battery and a second version of the electrodynamic parameter computed from a second battery measurement taken in a rest period where the current signal at the battery is reduced relative to when the first battery measurement was taken; and generating a current signal at the battery based on the electrodynamic parameter where at least some effects of thermal noise have been removed.

In various arrangements, the battery measurement includes at least one of a voltage measurement, a current measurement, a temperature measurement and an impedance measurement. The electrodynamic parameter includes at least one of Lyapunov Exponent, Entropy related parameters such as Sample Entropy, Correlation Dimension and Hurst Exponent.

Generating the current signal at the battery may be based on a harmonic value associated with a relatively lower electrodynamic parameter as compared to other harmonic values associated with a relatively higher electrodynamic parameter.

In some arrangements, the second version of the electrodynamic parameter is computed from a battery measurement obtained in the rest period which is associated with a relaxed equilibrium state of the battery. The relaxed equilibrium state of the battery may be during a zero-net change to the battery. In contrast, the first version of the electrodynamic parameter may be computed from a battery measurement obtained in the presence of a current signal that includes a transient state of the battery, such as a transition to rest period from a pulse or an active charge signal.

Another aspect of the present disclosure involves a method of charging a battery comprising: generating an entropy electrodynamic parameter from a first version of the electrodynamic parameter computed from a first battery measurement of voltage taken in the presence of a probe signal at a battery and removing, from the first version, a second version of the electrodynamic parameter computed from a second battery measurement taken in a rest period following the probe signal where contributions to the second version of the electrodynamic parameter are influenced by thermal noise, and generating a charge signal at the battery based on the entropy electrodynamic parameter.

Generating a charge signal may comprise altering at least one of harmonic content of the charge signal, duty cycle of the charge signal, charge current magnitude of the charge signal, and charge voltage of the charge signal. The entropy electrodynamic parameter may be sample entropy.

In some arrangements, the second version of the entropy electrodynamic parameter is computed from a battery measurement obtained in the rest period, which is associated with a relaxed equilibrium state of the battery. The relaxed equilibrium state of the battery may be during a zero-net change to the battery. In contrast, the first version of the entropy electrodynamic parameter may be computed from a battery measurement obtained in the presence of a current signal includes a transient state of the battery.

These and other aspects of the disclosure are described in further detail below.

### BRIEF DESCRIPTION OF THE DRAWINGS

FIG. 1 is a diagram of probe signal, which may also be a shaped charging signal, illustrating a transient time A when data may be sampled for further processing and steady state times B and/or C when data may also be sampled for further processing.

FIG. 2 is an example of a signal captured at a transient time A of FIG. 1.

FIG. 3 is an example of bifurcation and Lyapunov constant diagrams generated in accordance with aspects of the present disclosure and reflective of electrochemical and electrodynamic battery cell processes, and part of generating information and actions concerning the same.

FIG. 4 is an example of a method of generating an electrodynamic parameter after removing some or all of the contributions from thermal noise, the parameter then useful in defining a charge signal to a battery.

FIG. 5 are other examples of probe signals.

FIG. 6A is an example of sample entropy computations including contributions from thermal noise and electrodynamic or other effects within the battery.

FIG. 6B is an example of sample entropy computations including contributions primarily from thermal noise.

FIG. 6C is an example of sample entropy after removing the effects of thermal noise of FIG. 6B from the computations of FIG. 6A.

FIG. 7 is an example of harmonic spectrum information and sample entropy, which may be useful in defining a charge signal.

FIG. 8 is one example of a computer system that may be used to implement the methods discussed herein.

### DETAILED DESCRIPTION

Aspects of the present disclosure involve a new understanding that electrodynamic and electrochemical processes in electrochemical systems, particularly rechargeable batteries, may be identified from what would normally be considered discardable data. In a general sense, “noise” in electrical systems is considered to consist of uncorrelated completely random signal data and is typically ignored or efforts are made to suppress or remove it. In the present application, however, signals that would normally be considered noisy are understood to contain information that may be associated with events occurring in the battery. The detection of such events and the manipulation of such signals, alone or in combination, may be further used to alter various actions on the battery such as charging or discharging. While aspects of this disclosure are discussed primarily in the context of battery charging and discharging, aspects of the disclosure are also applicable to other environments including electroplating systems.

The term “battery” in the art and herein can be used in various ways and may refer to an individual cell having an anode and cathode separated by an electrolyte, solid or liquid, as well as a collection of such cells connected in various arrangements. A battery or battery cell is a form of electrochemical device. Batteries generally comprise repeating units of sources of a countercharge and electrode layers separated by an ionically conductive barrier, often a liquid or polymer membrane saturated with an electrolyte. These layers are made to be thin so multiple units can occupy the volume of a battery, increasing the available power of the battery with each stacked unit. Although many examples are discussed herein as applicable to a battery, it should be appreciated that the systems and methods described may apply to many different types of batteries ranging from an individual cell to batteries involving different possible interconnections of cells such as cells coupled in parallel, series, and parallel and series. For example, the systems and methods discussed herein may apply to a battery pack comprising numerous cells arranged to provide a defined pack voltage, output current, and/or capacity. Moreover, the implementations discussed herein may apply to different types of electrochemical devices such as various different types of lithium batteries including but not limited to lithium-metal and lithium-ion batteries, lead-acid batteries, various types of nickel batteries, and solid-state batteries, to name a few. The various implementations discussed herein may also apply to different structural battery arrangements such as button or “coin” type batteries, cylindrical cells, pouch cells, and prismatic cells.

To begin, an unfiltered signal, which may appear noisy, or carefully filtered signal, which may appear less noisy, is captured from the battery. For example, the system may include a filter or filters targeted at filtering out readily identified hardware or other forms of ancillary noise. Stated differently, the filter or filters may be set or defined to remove signal data that is known to be related to hardware and environmental contributions (e.g., thermal effects) and not be related to battery dynamics, such as internal battery electrodynamics. The signal may be captured during steady state (equilibrium). The signal may also be captured in the presence of a probe signal. The probe signal may be a dedicated probing signal or may be a charge signal. The signal may also be captured during discharge. In one specific example, the probe signal is a charge signal and includes transient portions and steady state portions. The signal may also be captured in the presence of a charge or probe signal and afterward when no charge (or discharge) is present. In either or both situations, the signal may be captured during equilibrium.

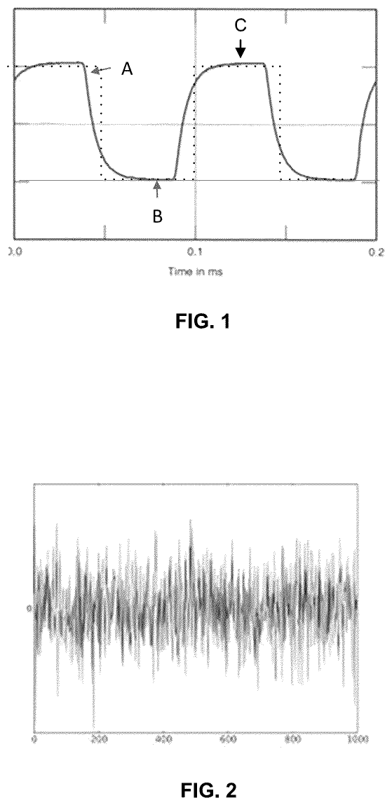

FIG. 1 illustrates an example charge signal that includes a transient portion at A and relatively steady state portions at B and C. A probe signal may similarly have transient and/or steady portions. The y-axis in this diagram is voltage ranging from about 0 (versus open circuit at the battery terminals) to about 5 volts for many conventional single Lithium-Ion cells with an open circuit voltage of about 4.2 volts although it can be higher; however, it may also be current and display a similar waveform. The upper voltage range is dependent on a number of factors and the example here is merely provided for relative reference. As seen at locations B and C, the signal is at a steady state voltage (e.g., changing less than some set percentage, e.g., 1%, 2%, 5% or 10%) if even only for about 0.25 ms. As noted below, the steady state of the portion B may be extended to help ensure the battery has fully relaxed, in some examples. At location A, in contrast, the signal rapidly drops from a first steady state to a lower second steady state over a time of about 0.25 ms, with the transition area, between steady states, being transient. Data may be captured at time A and/or at time B and/or at time C. Of note, the charge signal here is tailored to not include any sharp high frequency charge edges associated with pulse charging, which would be in the form of a square wave (shown in dashed line for comparative purposes) with about 90 degree transitions, and the charge signal here is not considered pulse charging. Techniques discussed herein, however, may be used to modify pulse charging signals. Data may also be captured at other points, with A, B and C simply being examples. In the example signal, A is a point immediately following the cessation of charge current but while the charge voltage is beginning to descend to zero after the cessation of charge current. Point B is at a point after the charge current and charge voltage are about zero and before the initiation of a subsequent charge energy. C indicates an actively controlled and stimulated point of current and voltage.

FIG. 2 is an illustration of a signal captured at point A. Data captured at point B will have a similar quality albeit the signal will include information associated with a temporary steady state as opposed to transient processes within the cell. Similarly, data at point C will contain information about processes associated with electrical activity inside the cell concurrent with a particular current and potential. During battery charging (or discharging), there are many electrochemical and electrodynamic effects occurring within the battery. These effects vary based on the among of charging current being applied, the temperature of the battery, the number of charge-cycles the battery has experienced, the battery chemistry and other influences. Electrochemical and electrodynamic effects or information indicative of the same may be present in the captured data.

More particularly and as introduced above, within the noisy appearing data are correlated signals masquerading as uncorrelated noise. This correlated data is captured with the uncorrelated information. The correlated (deterministic) signals are associated with electrochemical and electrodynamic processes occurring within the battery. As such, and in accordance with aspects of the present disclosure, a myriad of useful information may be obtained by isolating the correlated information from the inherently uncorrelated (e.g., thermal), associating that information with some event occurring in the battery, and/or then acting on that information and event correlation to alter charge, discharge, characterization parameters or other actions on or in relation to the battery. In some instances, “correlated data” and “a correlated signal” may refer to data or signals which have been modified to reduce, but not necessarily fully eliminate, contributions from thermal noise. Conventionally, there has not believed to have been a recognition that there is an association between electrochemical and electrodynamic information and correlated signal character hidden within complex noise. Similarly, there has not been any attempt to use such information to manage electrical energy used to charge or discharge a battery, electroplate or otherwise.

In one example, during equilibrium (steady state), when there is no charge or discharge of the battery (e.g., at point B), there are some electrochemical processes occurring involving ion diffusion, intercalation and deintercalation, for example. Typically, there are no net changes associated with such equilibrium activity. In a relaxed state, there is a relative settling of the voltage relative to transient current or voltage behavior. These steady state processes are nonetheless reflected in and can be identified from correlated signals that may be isolated from and otherwise detected in the measured signal.

In another example, correlated signals within the broader data signal may be reflective of lithium plating and may be used to identify such events. Lithium plating can lead to dendrite growth among other concerns. During charging, lithium ions from the cathode insert into the anode in a process referred to as intercalation. At the same time, lithium may plate the anode, which is undesirable and can lead to various problems including capacity degradation and increased internal cell resistance. Dendrite growth can be associated with capacity degradation and also further lead to short circuit conditions, which may lead to battery failure. There are some known causes for plating including charging at a rate that exceeds the rate at which some ions can intercalate (a rate considered too high) and charging at too low a temperature where diffusion is hindered, and the anode becomes highly polarized. Besides altering a charge signal, upon determination of the onset of plating, the system may also wait until temperature increases to an acceptable threshold to resume charging.

In accordance with aspects of the present disclosure, it has been further discovered that plating, including dendrite formation and growth, may also be caused or exacerbated by uncontrolled charge signal noise, particularly relatively high frequency charge signal noise. This noise may originate from processes inside the cell, from external sources such as nearby electrical components or radiating signals, or from frequent alternation between net charge and discharge states, and other sources. Uncontrolled charge signal noise is seen to be associated with electrodynamic effects and conductive pathway concentration in the anode, cathode, and/or associated current collectors. The electrodynamic noise induced conductive pathways may then cause localized current concentrations leading to plating and dendrite formation. Aspects of the present disclosure thus involve identifying such conditions, and countering or otherwise mitigating uncontrolled noise.

To address some or all of these issues, as well as others, one particular aspect of the present disclosure involves identifying plating within the unaltered or carefully altered (e.g., filtered, as discussed above) signal and further may involve altering some condition (e.g., some aspect of the charge signal) to reduce or eliminate plating. The ability to detect plating in the data, which may be a part of an otherwise noisy signal with uncorrelated data, may be based, at least in part, by the realization that plating, and dendrite formation and growth are 3-dimensional, and sometimes fractal in nature. Filtering signal data to isolate or otherwise identify the correlated content, and then further processing, which may involve various assessments of statistical and deterministic nature, may be used to identify plating and act on it.

In terms of state of charge and as introduced above regarding plating, charging involves ion diffusion from the cathode to the anode. As the state of charge rises, the diffusion patterns change as available ions in the cathode and the intercalation activity at the anode declines. This activity is reflected in correlated signals within signal the data from a battery, related to both electrochemical and electrodynamic processes, and may thus be identified according to the techniques discussed herein.

While many processes are in play within a battery while it is being charged, in one example, one favorable and what might be considered normal and harmless process within the battery involves ion diffusion from the cathode to the anode. As mentioned above, under some unfavorable charge conditions, plating and dendrite growth may occur. It is also the case that as a battery approaches a full state of charge, the diffusive processes from the cathode to the anode reduce as the available lithium inventory lessens. The energy normally that would be going to battery healthy charging may then instead go into plating. In conventional processes because the electrokinetics of diffusion and plating are dependent and occur in series, the two processes are exceedingly difficult to distinguish and the onset of plating exceedingly difficult to distinguish from healthy charge transfer reactions. In one aspect of the present disclosure, however, correlated data during charge is processed to identify bifurcations. The onset of a bifurcation is representative of the onset of a distinct process within the data. In the case of correlated data extracted from a data signal during charge, a method may involve generating a bifurcation data set (commonly displayed as a bifurcation diagram) and identifying the occurrence of a bifurcation. Once thermal noise is removed, the remaining data may still tend toward uncorrelated behavior if a secondary process (such as plating, or electrolyte degradation) starts to onset. These shifts toward uncorrelated character would normally be temporary. Nonetheless, in some instances, the removal of thermal noise allows the system to better identify and isolate correlated data and compute dynamic parameters useful in the same. Leading to the bifurcation may be indicative of change from healthy diffusion during charge and the transition to an additional process, such as plating, at the bifurcation indicative that charge energy is being used for both charging and plating. As such, upon the identification of a bifurcation, the system may alter the charge signal, such as by reducing the charge current, reducing the charge voltage, reducing both, altering a duty cycle, altering charge signal characteristics such as shape, or making other charge signal changes.

Healthy cathodic phase changes may also occur during charging. Such a change may also be identified through a bifurcation. Assessing state of charge or acting on information during charging may be based on various parameters such as identifying the onset of plating and identifying cathodic phase changes, alone or in a myriad of combinations. For example, in the presence of a bifurcation related to the onset of plating, a charge signal may be reduced (e.g., reducing charge current), as noted above, to thereby reduce anode overpotential to have the effect of stopping plating. The system may then assess or assume that plating has been halted and continue analyzing the correlated data until the onset of another bifurcation, and then repeat the process (altering charge parameters). It should be recognized that the process may be done in conjunction with an SOC assessment, or voltage level assessment, or other additional sets of information to identify when charging is complete—e.g., 100%.

The non-uniform plating and dendrite formation and growth, among other things, may be understood to be fractal in nature. Moreover, some processes and other battery processes that are fractal in nature are considered undesirable, while others may be considered normal and not damaging or otherwise undesirable. As such, correlated data within the signal may generally be characterized as fractal, which leads to opportunities to process the data as the same, and then associate the data with some undesirable or favorable processes within the cell. Moreover, when correlated signals are isolated from actual noise in the signal, the correlated signals may be processed using various statistical analytical techniques, some of which are directly or tangentially related to impedance and electrochemical physics, and others which are distinct from impedance-based parameters and reflective of broader electrodynamics. Numerous examples are possible including the generation of bifurcation data as discussed above and the generation of a Lyapunov Exponent or Sample Entropy. Such may be correlated in relation to state of charge, state of health, instantaneous degradation, temperature distribution, voltage, current, impedance, and other useful metrics. Processing, alone or in various processing combinations, of the correlated signals yields information indicative of various desirable or otherwise normal electrochemical and electrodynamic processes as well as undesirable processes.

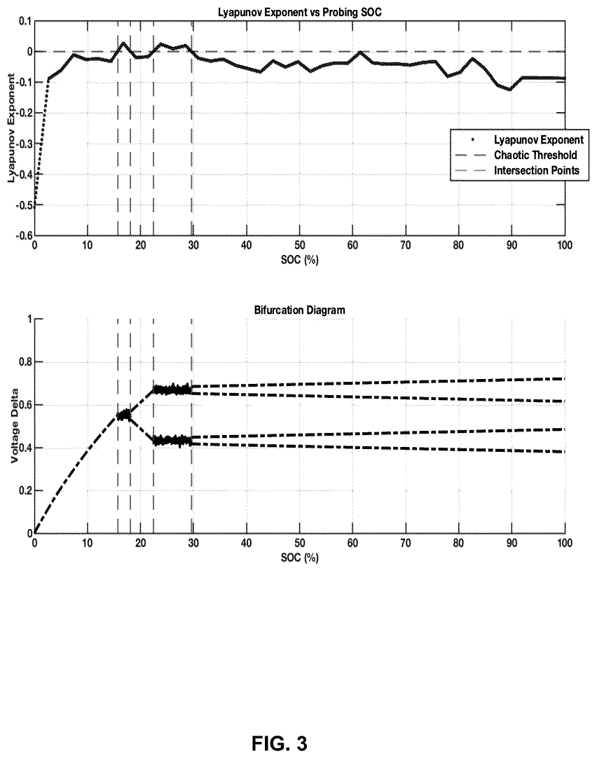

FIG. 3 is an example of a bifurcation diagram. In this example, the y-axis is voltage, although the same analysis could be performed with current or impedance, among other calculated values, derived or referenced values, or combinations of values. The x-axis is State of Charge (SOC). In general, Lyapunov is a parameter that may be used to identify and qualify behaviors of correlated information within otherwise nonsensical data. Positive values indicate increasingly uncorrelated behavior. Negative values indicate periodic behavior. Values close to or at zero indicate the onset of chaotic behavior while trends which cross zero indicate at least a bifurcation in the measured parameter. Truly uncorrelated data such as noise or thermal processes are reflected by large positive values. In FIG. 3, the current is held at 2 C during a complete charge cycle to show how the Lyapunov starts with periodic character which quickly becomes chaotic. Positive values are sustained for short periods, during which the activity in the cell, and at the electrodes, in particular, is irregular as portions of the electrode surface transition to a new mechanism of electron exchange. This phenomenon is measured nearly instantaneously and would go entirely unobserved in conventional impedance-based forms of analysis. As noted above, a bifurcation can imply the onset of two or more parallel pathways in the data. Above 20% SOC, the onset of a second pathway is identified. The pathways are continued to 100% SOC in this plot to indicate the battery's susceptibility. In practice, the detection of a bifurcation during charge would lead to quick adjustment of the charge signal, such as a decrease in current or voltage which would terminate the lithium plating pathway. This method, alone or combined with other analysis, may be used to detect the onset of lithium plating occurring parallel to intercalation associated with healthy charging and ion diffusion. Multiple parameters in combination can be used to identify key behaviors for any battery chemistry, size or architecture, as well as for electrochemical systems in general.

The information itself is valuable in characterizing a battery and is valuable in charge or discharge control of a battery, as well as other values, such as health generation of the battery (a process which is neither charging or discharging in a conventional sense). The information may also be useful in charge or discharge control. For example, detection of early onset plating, and modification of the charge signal to avoid the same contributes to longer battery cycle life, battery capacity, charge rate, capacity utilization, and battery safety among other things. Detection of state of charge has a myriad of similar advantages including greater battery capacity utilization, effective charge rate control, discharge control, greater cycle life, and battery safety overall.

Thermal and random effects can both be removed by assessing the stochastic nature of the signal based upon consistent measurements which don't change with sampling rate or sampled time. In one example, data from the charging signal of a battery is collected which spans a material phase transition of the cathode. The data is parsed into three individual periods, before, during and after the phase transition. Each period is analyzed independently, measuring degree of randomness (e.g., through a BDS analysis or entropy) and whether or not this degree changes when different sampling rates and periods are used within the parsed data. The degree of randomness which is maintained despite sample rates and periods within one of the three parsed sets can be taken as a thermal baseline, and the degree of randomness may be filtered from the data for a period in which the system is known to be semi/stable. The resulting variations in data behavior which arise from subsequent deterministic calculations will have higher accuracy and will, in many cases, be more suitable for understanding internal battery dynamics.

According to aspects of the present disclosure, a method involves filtering thermal or other noise from signal data, computing one or more electrodynamic parameters (e.g., Sample Entropy, Lyapunov Exponent, Correlation Dimension), and altering a signal at the battery (e.g., charge or discharge) based on the same.

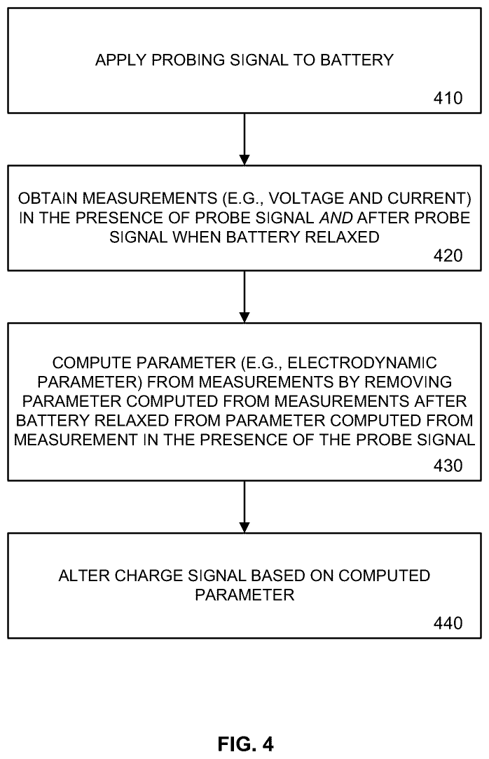

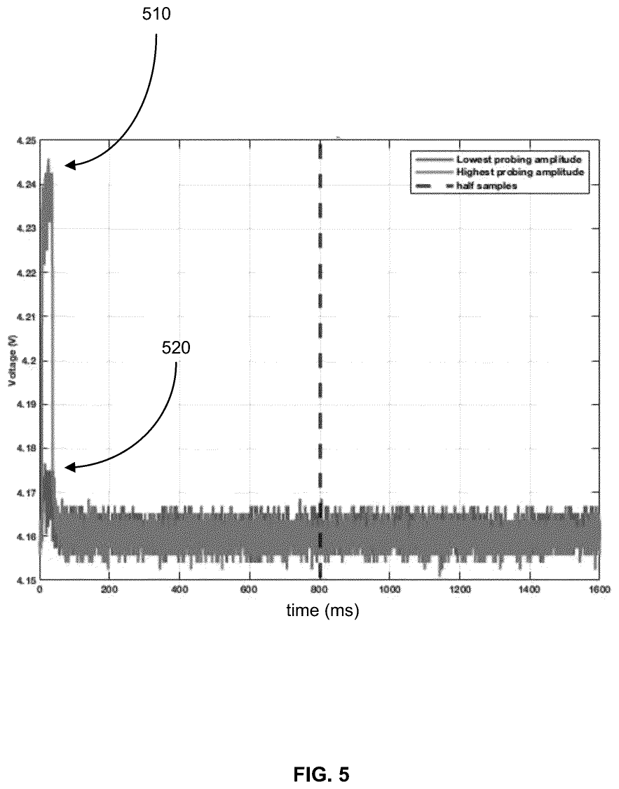

FIG. 4 illustrates a method of altering a charge signal (or discharge signal) based on an electrodynamic parameter and where the contribution from thermal noise is removed from the electrodynamic parameter. To begin, a probe signal is applied to the battery (operation 410). The probe signals of FIG. 1 and FIG. 5 are examples of possible probe signals. However, a probing signal could also take on a purely transitional or even arbitrary shape for more targeted dynamical analysis. For example, the probe may involve a steadily increasing current rather than a pulse or steady current, and monitor the noise. When degradation is detected, the system may then start ramping the current back down gradually.

In the illustrated probe examples, the probe signal includes a current at a voltage and is of limited duration. Current and voltage signal measurements may be taken when the probe signal is active and after the probe signal is inactive and the battery has relaxed (operation 420). Further, the probe signal may be applied when charging (or discharging) is momentarily halted so the battery is not under charge (or discharge) and there is no other current in or from the battery.

FIG. 5 illustrates two examples of probe signals (510 and 520) applied to a battery. The probe signal has an initial peak voltage when current is applied to the battery of about 4.24 volts and 4.18 volts respectively, and the battery relaxes to a voltage signal of about a nominal 4.16 volts (+/−0.05 volts) after each probe signal is not active (no probing current applied). In this example, the probe voltage is below the maximum allowed voltage of the battery. The voltage measurements during the relaxed period show voltage measurement variations (including from thermal noise) between less than 4.17 volts and greater than 4.15 volts, centered at about 4.16 volts. In this example, the probe voltage is chosen to be very close to the nominal open circuit voltage of the cell at the current SOC so that the modest overpotential introduced by the probe relaxes quickly. Here, the measurements are used about 750 ms after the battery has relaxed. While overlayed in the Figure, the two pulse-based probe signals were applied in a serial manner, one after the other.

In general, a probing signal is formulated to induce whatever dynamics are to be analyzed. In some cases, for example, the charge signal may suffice if the need is to generate an electrodynamic parameter associated with a probe of the active dynamics of charging. Alternatively, to generate electrodynamic parameters associated with the dynamics of the overpotential across the battery or its electrodes, the probe may include a rest period during which the dynamics during the relaxation period (and relaxation of overpotential) can be measured and parameters computed. In another case, it may be useful to generate a short pulse with currents which are greater than the present charging current, so as to probe the dynamics at that higher current and understand how much more “headroom” is available before dynamics associated with degradation begin. In this case, the timing of the probing signal should be > or = the characteristic time of the kinetics we wish to probe. The kinetics could be associated with electrochemical dynamics OR purely electrical dynamics. In another case, if we want to understand the dynamics induced by a particular frequency, then the system would apply a sinusoidal probing signal, obtain data from the same and generate one or more parameters.

In some examples, for purposes of subsequent operations, the relaxed voltage measurements may be made some time after the probe signal is discontinued. In the example of FIG. 5, such measurements may be made between 800 and 1600 milliseconds after the pulse is initiated, where the pulse is of about 50 milliseconds. So, measurements are made about 750 milliseconds after the pulse is discontinued and when the battery has relaxed. Measurements are also made during the initial 50 milliseconds while the pulse is active, and related to transient conditions from the probe. An electrodynamic parameter computed from measurements while the pulse is active contains information correlated to processes of interest occurring within the cell as well as contributions from thermal noise. When the battery has relaxed, the measurements are considered to not be from electrochemical processes within the cell, and instead can be considered to be partly or mainly from thermal noise, which is chaotic and can affect the accuracy and reliability of other measurements including electrodynamic determinations. The specific timing of FIG. 5 is but one example. The battery in this example is a rechargeable 3 Ah Lithium Metal pouch cell with a 3.8V nominal voltage. Other battery chemistries (e.g., Lithium Ion), battery sizes, etc., may affect the definition of the pulse (probe length, voltage, relaxation timing) and what measurements during the pulse and after are used in computing an electrodynamic or other parameter.

Generally speaking, measurements should be made between a time when the pulse is active and a charge current (at some voltage) is applied to the battery cell (e.g., an active part of the probing pulse) and a time when no probe current is applied to the battery after the pulse, and the battery cell is in a relaxed state. In some instances, the probe signal is a part of a charge signal (effectively the charge signal itself) and measurements are taken when the charge current is active, and then during a period while the charge current is not applied, and the battery is in a relaxed state, which may be immediately after the charge current is discontinued. From these measurements, electrodynamic parameters may be computed as discussed herein, with the effects of thermal noise then removed from the electrodynamic parameter(s) being assessed. In some examples, the different measurements are also made between times when the internal cell temperature has likely not changed. In some examples, because the measurements are taken in very close proximity (timewise), there is likely no other change between the two measurement so the SE portion is the same and removing the thermal contribution clarifies the SE value. For example, the cell temperature will likely have not changed in the 750 ms between the measurements during the probe and the measurements in the relaxed state. As such, the electrodynamic parameter should not meaningfully change between measurements and the contribution from thermal noise be consistent between the measurements. Internal cell temperature changes and the rate of such changes may depend on the charge rate, internal or external temperature of the cell, state of charge and other factors. The contribution from thermal noise may be relatively larger when a battery is being charged at a relatively higher rate; thus, the need to remove contributions from thermal noise may be more acute in higher charge rate systems, where it also may be relatively more advantageous to also include more sophisticated charging schemes such as those incorporating electrodynamic parameters and harmonically tuned charging signals based, at least in part, on such parameters.

An electrodynamic parameter or parameters may then be computed using the signal data (e.g., voltage) obtained when the probing pulse is present and after when the battery is relaxed.

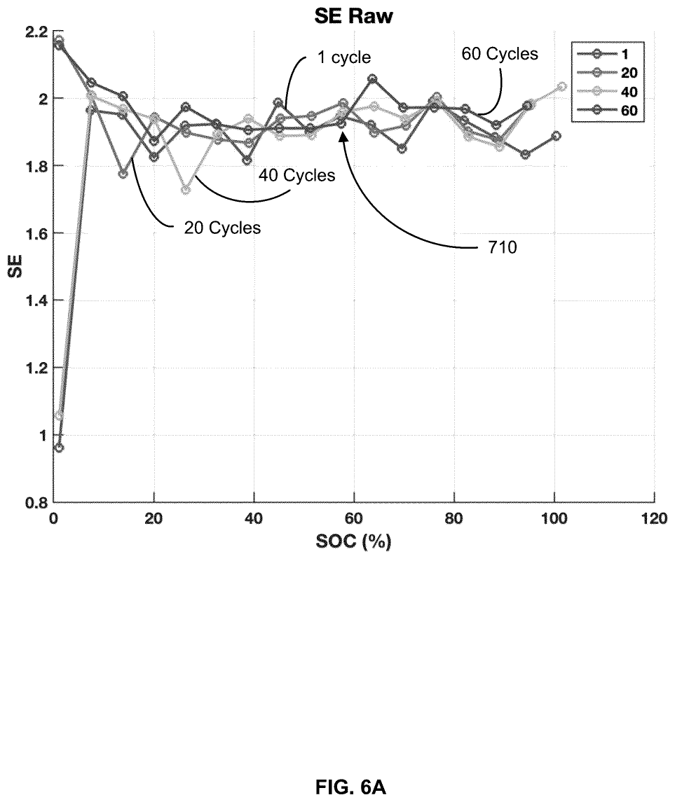

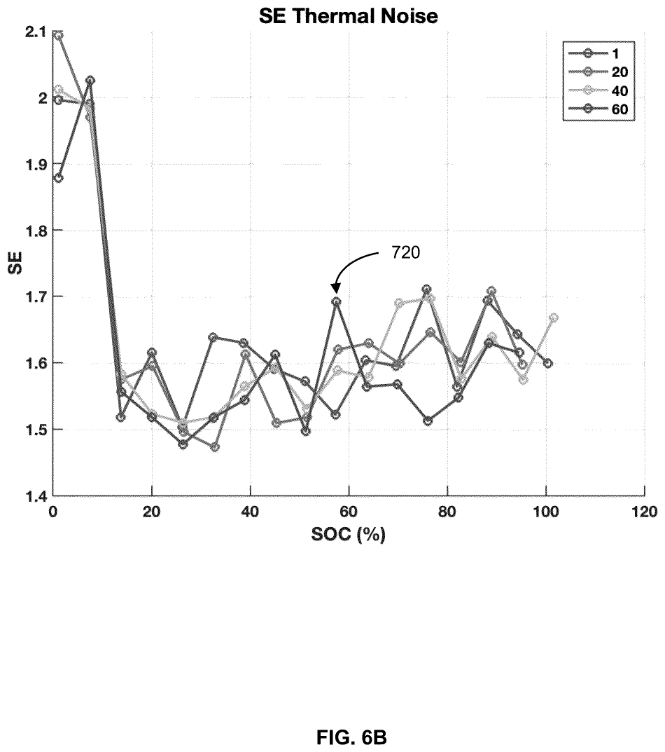

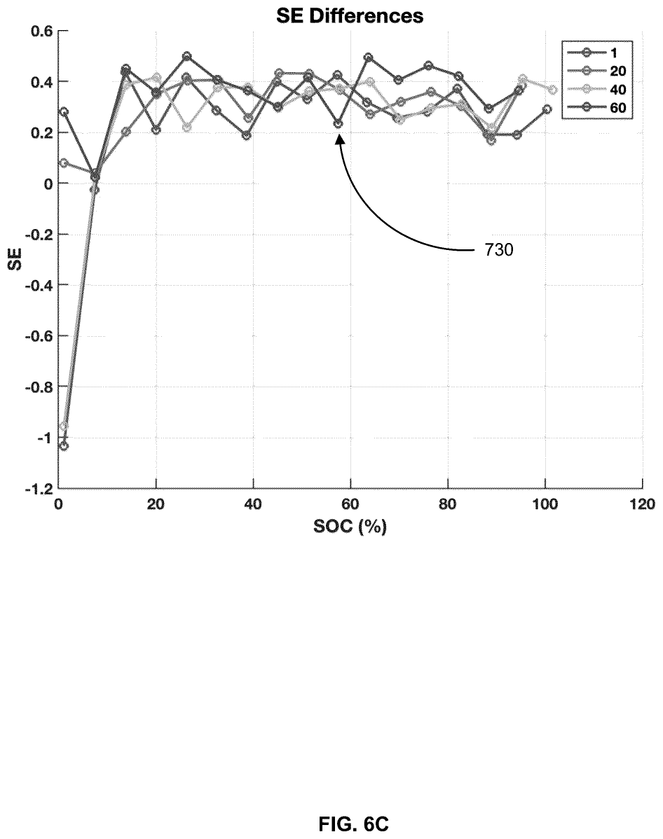

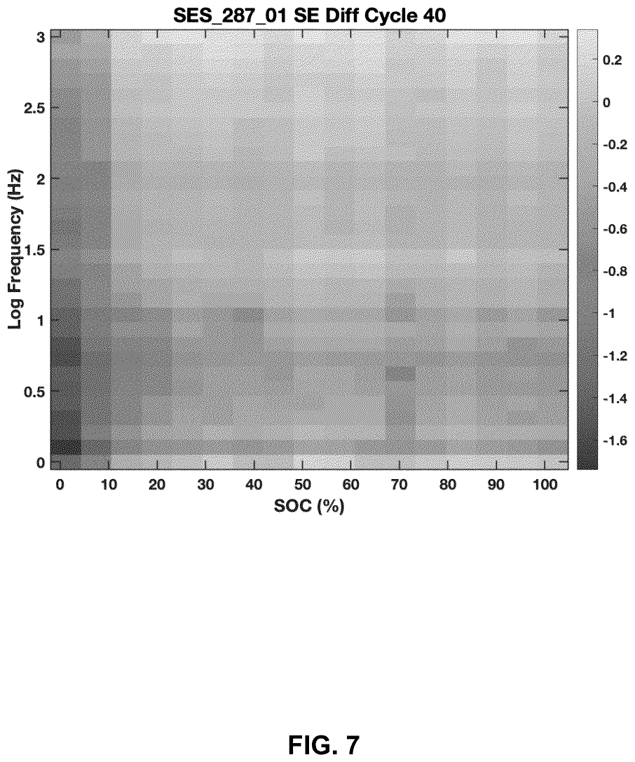

In an example, the system may compute Sample Entropy (SE) of a same Lithium Metal cell at 10% SOC intervals. In the example illustrated between FIGS. 6A-6C, Sample Entropy is computed based on measurements of voltage when the probe signal is active (includes thermal noise and inputs from electrochemical reactions, among other things), computed based on measurements of voltage when the probe signal is not active (information is predominately thermal noise) and then a resulting Sample Entropy is determined from removing the Sample Entropy computed from noise (FIG. 6B) from the Sample Entropy when the probe signal is active (FIG. 6A) to remove or reduce the effect of thermal noise on the Sample Entropy computations (FIG. 6C). For example, at 60 cycles, the SE value at about 60% SOC, is about 1.95 in FIG. 6A, is about 1.7 in FIG. 6C, and thus about 0.25 (1.95-1.7=0.25). Thus, the SE value measured including thermal noise is 1.95 and without the thermal noise is 0.25. In this case, there is a meaningfully greater contribution from thermal noise and not the electrodynamic effect being targeted through the SE value. Stated differently, the SE computation is sensitive to and effected by thermal noise.

In the example of Sample Entropy, the thermal noise contribution is removed by subtracting the respective value computed when the battery system is at rest (e.g., after the probe signal) from the respective value computed when the probe signal is active (e.g., in the presence of charge current and/or voltage exceeding the threshold voltage of the battery at rest). In other examples, the electrodynamic values, with and without thermal noise, may go through some form of preprocessing before subsequent operations to remove or reduce the effect of system noise (other than thermal noise) on the dynamic component. Such preprocessing may include averaging or other similar techniques (mean, median) and other data processing techniques. In addition, thermal noise may be removed or reduced through techniques besides subtraction including scaling and normalization.

Sample entropy is a measure of the complexity and regularity of a time series. It can be used to assess the health of a lithium-ion battery by analyzing its charging voltage or current waveform. While the term and example of SE is discussed herein, the term is meant to refer to various calculations of entropy and represents an example of signal entropy.
Step 1: Data Preparation: First, the system uses a sequence length (m) and a tolerance value (r) for similarity comparisons. The sequence length (m) determines how many data points the system compare at a time, and the tolerance (r) defines the acceptable range for considering two data points similar.
Step 2. Template Matching: The system then calculates the number of data sequences of length (m) that have a similar counterpart within a tolerance (r) for the next (m−1) data points. Here, similarity refers to the voltage or current values being within the tolerance range. Mathematically, the system can represent this count as Bm.
Step 3: Subsequence Comparison: Similarly, the systems repeats step 2 but excludes the first data point from the original sequence. This gives us the number of similar sequences of length (m−1) within the tolerance (r), denoted by Am.
Step 4. Sample Entropy Calculation: Finally, sample entropy is calculated using the following formula:

SampEn=−ln(Am/Bm)

After the effects of thermal noise are removed or reduced relative to the electrodynamic parameter being assessed, the dynamic parameter may be used, alone or in various combinations, to define or influence some aspect of a charge (or discharge signal). With respect to the Sample Entropy, it has been observed that a relatively lower magnitude value may be associated with a charge signal that is more efficient, generates less heat, is associated with less plating, and/or is associated with relatively less dendritic growth.

FIG. 9 is a chart showing the Sample Entropy, after noise removal, for a battery cell from 0 to 100% SOC (after having been cycled 40 times). It can be seen that there is a band of harmonics between 0.1 and 1 (on a log scale of Hz) at which the SE value is relatively lower (e.g., between −0.4 and −0.8) as compared to other frequencies, noting that there are discrete frequencies outside that range associated with similarly lower SE values. From the SE diagram and the distinct bands of lower and higher entropy, the information can be used to understand the entropic stability of the battery with SOC (where higher stability is generally preferable for long term cycle life), to inform thermodynamic models, and to inform State of Health assessment in combination with other parameters. Additionally in the particular battery analyzed, frequencies of about 2.5(log Hz) appear to offer relative stability compared to higher and lower frequencies.

In terms of using the information from electrodynamic values removing or reducing the effect of thermal noise, the approach of examining individual frequencies could be used to build any type of charging waveform. For example, single or multi-harmonic AC charging signals composed of some favorable or combination of favorable harmonics may be selected. Examples of systems and method for controlling charge signal harmonic content is described in in co-pending U.S. patent application Ser. No. 17/473,828 (publication 2022/0085633) titled “Systems and Methods for Harmonic-Based Battery Charging,” filed Sep. 13, 2021 and published on Mar. 17, 2022, which is hereby incorporated by reference herein. In another example, the analysis and harmonic information could also inform the healthiest harmonic content for transitions, such as step increases in DC current, or starting transitions for charging sequences. Examples of systems and method for generating charge signals is described in in co-pending U.S. patent application Ser. No. 17/390,851 (publication 2022/0029443) titled “Systems and Methods for Electrochemical Device Charging and Discharging,” filed Jul. 30, 2021, which is hereby incorporated by reference herein. The leading edge of the signal may be shaped based on a sinusoid, and the sinusoidal shape may be at a frequency at one of the values where the LE values is between −6 and −7. In another example, the body portion the charge signal may be composed of a set of harmonics associated with the LE values between −6 and −7. Conversely or additionally, a harmonic or sets of harmonics may be excluded or filtered from a charge signal so that those harmonics are not included.

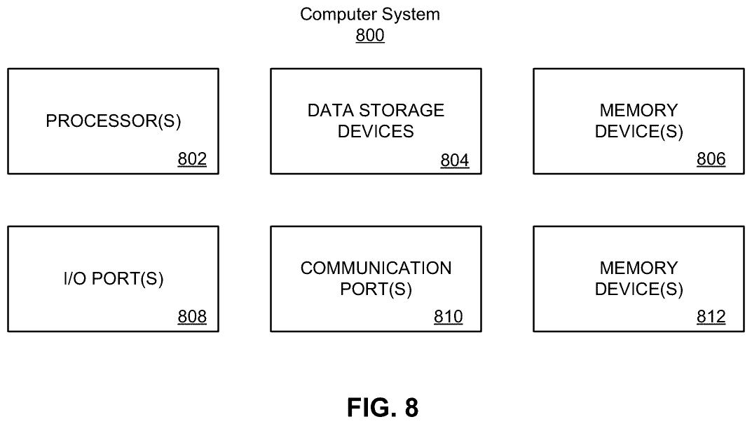

Referring to FIG. 8, a detailed description of an example computing system 800 having one or more computing units that may implement various systems and methods discussed herein is provided. The computing system 800 may be part of a controller, may be in operable communication with various implementation discussed herein, may run various operations related to the method discussed herein, may run offline to process various data for characterizing a battery, and may be part of overall systems discussed herein. More or fewer components of the system 800 may be present in any possible implementation. In a system characterizing a battery or type of battery, a similar system may be involved as the system may be configured to implement various charge signals, process and analyze noise signals, and act on the same. User interfaces may also be involved to obtain inputs concerning the type of battery being characterized. In some applications, such as a power tool, relatively small mobile device like an e-bike, and some mobile computing applications, fewer or an otherwise more stripped-down system may be used. In some applications, system components of a wider system may be shared, such as in a mobile “smart” phone or tablet.

The computing system 800 may process various signals (e.g., FIGS. 1, 2) discussed herein and/or may provide various signals discussed herein. For example, battery measurement information which is uncorrelated to any particular interpretation, or vague or incorrect interpretations using other methods such as Electrochemical Impedance Spectroscopy, Non-linear Electrochemical Impedance Spectroscopy, Equivalent Circuit Models, empirically derived neural network-based models, or models based primarily upon thermal and electrochemical physics, may be provided to such a computing system 800. The system may run transforms against the same and analyze the same. The system may characterize a battery using the same or may control some process such as charging or discharging. It will be appreciated that specific implementations of these devices may be of differing possible specific computing architectures, not all of which are specifically discussed herein but will be understood by those of ordinary skill in the art. It will further be appreciated that the computer system may be considered and/or include an ASIC, FPGA, microcontroller, or other computing arrangement. In such various possible implementations, more or fewer components discussed below may be included, interconnections and other changes made, as will be understood by those of ordinary skill in the art.

The computer system 800 may be a computing system that is capable of executing a computer program product to execute a computer process. Data and program files may be input to the computer system 800, which reads the files and executes the programs therein. Some of the elements of the computer system 800 are shown in FIG. 8, including one or more hardware processors 802, one or more data storage devices 804, one or more memory devices 806, and/or one or more ports 808-812. Additionally, other elements that will be recognized by those skilled in the art may be included in the computing system 800 but are not explicitly depicted in FIG. 8 or discussed further herein. Various elements of the computer system 800 may communicate with one another by way of one or more communication buses, point-to-point communication paths, or other communication means not explicitly depicted in FIG. 8. Similarly, in various implementations, various elements disclosed in the system may or not be included in any given implementation.

The processor 802 may include, for example, a central processing unit (CPU), a microprocessor, a microcontroller, a digital signal processor (DSP), and/or one or more internal levels of cache. There may be one or more processors 802, such that the processor 802 comprises a single central-processing unit, or a plurality of processing units capable of executing instructions and performing operations in parallel with each other, commonly referred to as a parallel processing environment.

The presently described technology in various possible combinations may be implemented, at least in part, in software stored on the data stored device(s) 804, stored on the memory device(s) 806, and/or communicated via one or more of the ports 808-812, thereby transforming the computer system 800 in FIG. 8 to a special purpose machine for implementing the operations described herein.

The one or more data storage devices 804 may include any non-volatile data storage device capable of storing data generated or employed within the computing system 800, such as computer executable instructions for performing a computer process, which may include instructions of both application programs and an operating system (OS) that manages the various components of the computing system 800. The data storage devices 804 may include, without limitation, magnetic disk drives, optical disk drives, solid state drives (SSDs), flash drives, and the like. The data storage devices 804 may include removable data storage media, non-removable data storage media, and/or external storage devices made available via a wired or wireless network architecture with such computer program products, including one or more database management products, web server products, application server products, and/or other additional software components. Examples of removable data storage media include Compact Disc Read-Only Memory (CD-ROM), Digital Versatile Disc Read-Only Memory (DVD-ROM), magneto-optical disks, flash drives, and the like. Examples of non-removable data storage media include internal magnetic hard disks, SSDs, and the like. The one or more memory devices 806 may include volatile memory (e.g., dynamic random-access memory (DRAM), static random-access memory (SRAM), etc.) and/or non-volatile memory (e.g., read-only memory (ROM), flash memory, etc.).

Computer program products containing mechanisms to effectuate the systems and methods in accordance with the presently described technology may reside in the data storage devices 804 and/or the memory devices 806, which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures.

In some implementations, the computer system 800 includes one or more ports, such as an input/output (I/O) port 808, a communication port 810, and a sub-systems port 812, for communicating with other computing, network, or vehicle devices. It will be appreciated that the ports 808-812 may be combined or separate and that more or fewer ports may be included in the computer system 800. The I/O port 808 may be connected to an I/O device, or other device, by which information is input to or output from the computing system 800. Such I/O devices may include, without limitation, one or more input devices, output devices, and/or environment transducer devices.

In one implementation, the input devices convert a human-generated signal, such as, human voice, physical movement, physical touch or pressure, and/or the like, into electrical signals as input data into the computing system 800 via the I/O port 808. In some examples, such inputs may be distinct from the various system and method discussed with regard to the preceding figures. Similarly, the output devices may convert electrical signals received from computing system 800 via the I/O port 808 into signals that may be sensed or used by the various methods and system discussed herein. The input device may be an alphanumeric input device, including alphanumeric and other keys for communicating information and/or command selections to the processor 802 via the I/O port 808.

The environment transducer devices convert one form of energy or signal into another for input into or output from the computing system 800 via the I/O port 808. For example, an electrical signal generated within the computing system 800 may be converted to another type of signal, and/or vice-versa. In one implementation, the environment transducer devices sense characteristics or aspects of an environment local to or remote from the computing device 800, such as battery voltage, open circuit battery voltage, charge current, battery temperature, light, sound, temperature, pressure, magnetic field, electric field, chemical properties, and/or the like.

In one implementation, a communication port 810 may be connected to a network by way of which the computer system 800 may receive network data useful in executing the methods and systems set out herein as well as transmitting information and network configuration changes determined thereby. For example, charging protocols may be updated, battery measurement or calculation data shared with external system, and the like. The communication port 810 connects the computer system 800 to one or more communication interface devices configured to transmit and/or receive information between the computing system 800 and other devices by way of one or more wired or wireless communication networks or connections. Examples of such networks or connections include, without limitation, Universal Serial Bus (USB), Ethernet, Wi-Fi, Bluetooth®, Near Field Communication (NFC), Long-Term Evolution (LTE), and so on. One or more such communication interface devices may be utilized via the communication port 810 to communicate with one or more other machines, either directly over a point-to-point communication path, over a wide area network (WAN) (e.g., the Internet), over a local area network (LAN), over a cellular (e.g., third generation (3G), fourth generation (4G), fifth generation (5G)) network, or over another communication means.

The computer system 800 may include a sub-systems port 812 for communicating with one or more systems related to a device being charged according to the methods and system described herein to control an operation of the same and/or exchange information between the computer system 800 and one or more sub-systems of the device. Examples of such sub-systems of a vehicle, include, without limitation, motor controllers and systems, battery control systems, and others.

The system set forth in FIG. 8 is but one possible example of a computer system that may employ or be configured in accordance with aspects of the present disclosure. It will be appreciated that other non-transitory tangible computer-readable storage media storing computer-executable instructions for implementing the presently disclosed technology on a computing system may be utilized.

Embodiments of the present disclosure include various steps, which are described in this specification. The steps may be performed by hardware components or may be embodied in machine-executable instructions, which may be used to cause a general-purpose or special-purpose processor programmed with the instructions to perform the steps. Alternatively, the steps may be performed by a combination of hardware, software and/or firmware.

Various modifications and additions can be made to the exemplary embodiments discussed without departing from the scope of the present invention. For example, while the embodiments, also referred to as implementations or examples, described above refer to particular features, the scope of this invention also includes embodiments having different combinations of features and embodiments that do not include all of the described features. Accordingly, the scope of the present invention is intended to embrace all such alternatives, modifications, and variations together with all equivalents thereof.

While specific implementations are discussed, it should be understood that this is done for illustration purposes only. A person skilled in the relevant art will recognize that other components and configurations may be used without parting from the spirit and scope of the disclosure. Thus, the following description and drawings are illustrative and are not to be construed as limiting. Numerous specific details are described to provide a thorough understanding of the disclosure. However, in certain instances, well-known or conventional details are not described in order to avoid obscuring the description. References to one or an embodiment in the present disclosure can be references to the same embodiment or any embodiment; and, such references mean at least one of the embodiments.

Reference to “one embodiment” or “an embodiment” means that a particular feature, structure, or characteristic described in connection with the embodiment is included in at least one embodiment of the disclosure. The appearances of the phrase “in one embodiment”, or similarly “in one example” or “in one instance”, in various places in the specification are not necessarily all referring to the same embodiment, nor are separate or alternative embodiments mutually exclusive of other embodiments. Moreover, various features are described which may be exhibited by some embodiments and not by others.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. In some cases, synonyms for certain terms are provided. A recital of one or more synonyms does not exclude the use of other synonyms. The use of examples anywhere in this specification including examples of any terms discussed herein is illustrative only and is not intended to further limit the scope and meaning of the disclosure or of any example term. Likewise, the disclosure is not limited to various embodiments given in this specification.

Without intent to limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims or can be learned by the practice of the principles set forth herein.

What is claimed:

1. A method of charging a battery comprising:
generating an electrodynamic parameter from a first version of the electrodynamic parameter computed from a first battery measurement taken in the presence of a current signal at a battery and a second version of the electrodynamic parameter computed from a second battery measurement taken in a rest period where the current signal at the battery is reduced relative to when the first battery measurement was taken; and
generating a current signal at the battery based on the electrodynamic parameter where at least some effects of thermal noise have been removed.

2. The method of claim 1 wherein the battery measurement includes at least one of a voltage measurement, a current measurement, a temperature measurement and an impedance measurement.

3. The method of claim 1 further comprising generating the current signal at the battery based on a harmonic value associated with a relatively lower electrodynamic parameter as compared to other harmonic values associated with a relatively higher electrodynamic parameter.

4. The method of claim 1 wherein the electrodynamic parameter includes at least one of Lyapunov Exponent, Sample Entropy, Correlation Dimension and Hurst Exponent.

5. The method of claim 1 wherein the second version of the electrodynamic parameter is computed from a battery measurement obtained in the rest period is associated with a relaxed equilibrium state of the battery.

6. The method of claim 5 wherein the relaxed equilibrium state of the battery is during a zero-net change to the battery.

7. The method of claim 1 wherein the first version of the electrodynamic parameter is computed from a battery measurement obtained in the presence of a current signal includes a transient state of the battery.

8. The method of claim 7 wherein the transient state is associated with a charge signal, a discharge signal, or a probe signal.

9. A method of charging a battery comprising:
generating an entropy electrodynamic parameter from a first version of the electrodynamic parameter computed from a first battery measurement of voltage taken in the presence of a probe signal at a battery and removing, from the first version, a second version of the electrodynamic parameter computed from a second battery measurement taken in a rest period following the probe signal where contributions to the second version of the electrodynamic parameter are influenced by thermal noise, and
generating a charge signal at the battery based on the entropy electrodynamic parameter.

10. The method of claim 9 wherein generating a charge signal comprises altering at least one of harmonic content of the charge signal, duty cycle of the charge signal, charge current magnitude of the charge signal, and charge voltage of the charge signal.

11. The method of claim 9 wherein the entropy electrodynamic parameter is sample entropy.

12. The method of claim 1 wherein the second version of the entropy electrodynamic parameter is computed from a battery measurement obtained in the rest period is associated with a relaxed equilibrium state of the battery.

13. The method of claim 5 wherein the relaxed equilibrium state of the battery is during a zero-net change to the battery.

14. The method of claim 1 wherein the first version of the entropy electrodynamic parameter is computed from a battery measurement obtained in the presence of a current signal includes a transient state of the battery.
